(19) United States
(12) Patent Application Publication
(10) Pub. No.: US 2026/0130287 A1
(43) Pub. Date: May 7, 2026

(54) METHOD FOR MAKING LIGHT-EMITTING ASSEMBLY

(71) Applicant: Century Technology (Shenzhen) Corporation Limited, Shenzhen (CN)

(72) Inventor: KUANG-HUA LIU, Shenzhen (CN)

(21) Appl. No.: 19/437,600

(22) Filed: Dec. 31, 2025

Related U.S. Application Data
(62) Division of application No. 17/741,003, filed on May 10, 2022, now Pat. No. 12,543,595.

(30) Foreign Application Priority Data
Mar. 11, 2022 (CN) 202210238564.3

(51) Int. Cl. H10W 90/00; H10H 20/01; H10H 20/857; H10W 70/09; H10W 70/60; H10W 70/652

(52) U.S. Cl. CPC H10W 90/00; H10H 20/857; H10H 20/0364; H10W 70/09; H10W 70/60; H10W 70/6528

(57) ABSTRACT

A method of making light-emitting assembly, the method includes: providing a substrate comprising a driving circuit configured for outputting a first driving signal; forming a light-emitting diode on the substrate, the light-emitting diode comprising a first electrode, a second electrode, and a light-emitting layer between the first electrode and the second electrode, wherein the first electrode is connected to the driving circuit to receive the first driving signal; forming a transparent electrode on a side of the second electrode away from the light-emitting layer to connect the second electrode, and an orthographic projection area of the transparent electrode on the substrate being larger than an orthographic projection area of the second electrode on the substrate; and connecting the transparent electrode to a wire transmitting a second driving signal, so that the light-emitting layer emits source light according to the first driving signal and the second driving signal.

### FIELD

The present disclosure generally relates to lighting and display technology, particularly relates to a method for making the light-emitting assembly.

### BACKGROUND

A light-emitting diode (LED) is widely used in lighting devices, display devices, and the like. A vertical type of LED has an upper electrode, a lower electrode, and a light-emitting layer between the upper electrode and the lower electrode. When a voltage difference between the upper electrode and the lower electrode reaches a preset value, the light-emitting layer will emit light of a certain wavelength. A size of a single LED is very small (micron scale), so one lighting device or one display device always includes a plurality of closely arranged LEDs to achieve light-emitting or display. The upper electrode and/or the lower electrode of each LED needs to be electrically connected to other conductive structures by connecting wires. However, it is difficult to align the connecting wires with the upper electrode and/or the lower electrode of the LED because of the small size of a single LED, which causes misalignment, wherein a current loop cannot be formed, and the LED cannot emit light normally.

### BRIEF DESCRIPTION OF DRAWINGS

FIG. 1 illustrates a display device in a first embodiment of the present disclosure.

FIG. 2 is a cross-sectional view of a light-emitting assembly of the display device illustrated in FIG. 1.

FIG. 3 is a planar view of the light-emitting assembly illustrated in FIG. 2.

FIG. 4 illustrates a cross-sectional view of a light-emitting assembly in another embodiment of the present disclosure.

FIG. 5 is a flow chart of a method of making the light-emitting assembly in a first embodiment of the present disclosure.

FIG. 6 is a cross-sectional view of the light-emitting assembly after block S2 process of the flow chart shown in FIG. 5.

FIG. 7 is another cross-sectional view of the light-emitting assembly after block S2 of the flow chart shown in FIG. 5.

FIG. 8 is a cross-sectional view of the light-emitting assembly after block S3 process of the flow chart shown in FIG. 5.

FIG. 9 illustrates a display device in a second embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “comprising,” when utilized, means “including, but not necessarily limited to”; it specifically indicates open-ended inclusion or membership in the so-described combination, group, series, and the like.

“Above” means one layer is located on top of another layer. In one example, it means one layer is situated directly on top of another layer. In another example, it means one layer is situated over the second layer with more layers or spacers in between.

When a feature or element is herein referred to as being “on” another feature or element, it can be directly on the other feature or element or intervening features and/or elements may also be present. It will also be understood that, when a feature or element is referred to as being “connected”, “attached” or “coupled” to another feature or element, it can be directly connected, attached or coupled to the other feature or element or intervening features or elements may be present.

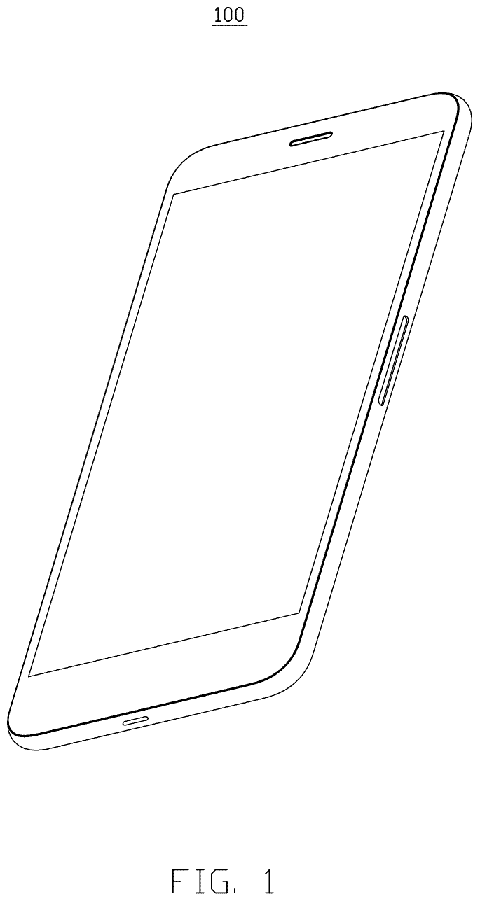

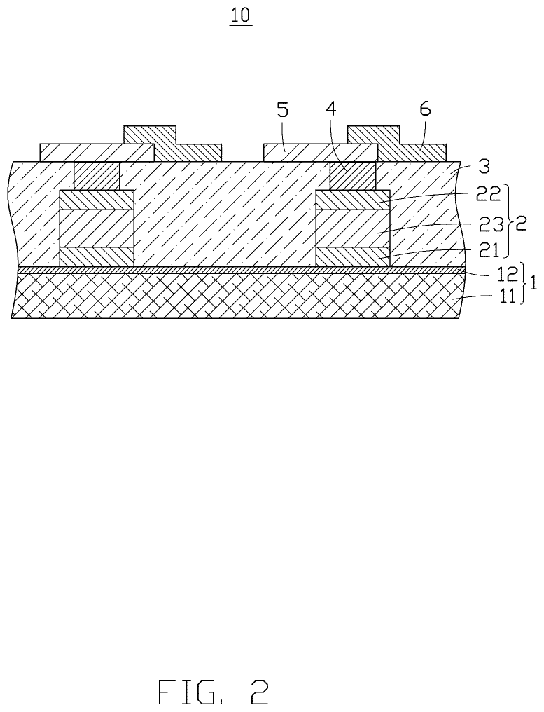

As shown in FIG. 1, a display device 100 is used to display images. The display device 100 is, for example, a smart device such as a mobile phone, a computer, a TV, or an outdoor display screen. In this embodiment, the display device 100 is a self-illuminating display device including a light-emitting assembly 10 shown in FIG. 2. The display device 100 may further include one or more optical function films (such as a brightness enhancement film, an antireflection film, etc., neither shown), an outer frame (not shown), or other structures.

As shown in FIG. 2, the light-emitting assembly 10 includes a substrate 1 and a plurality of light-emitting diodes (LEDs) 2 on a surface of the substrate 1.

In this embodiment, the substrate 1 includes a glass plate 11 and a driving circuit 12 on a surface of the glass plate 11. In this embodiment, the driving circuit 12 includes metal (such as copper) traces on the surface of the glass plate 11. The glass plate 11 is used for carrying and supporting, and the driving circuit 12 is used to provide electrical signals for the light-emitting assembly 10 to work. In this embodiment, the driving circuit 12 is used to output a first driving signal.

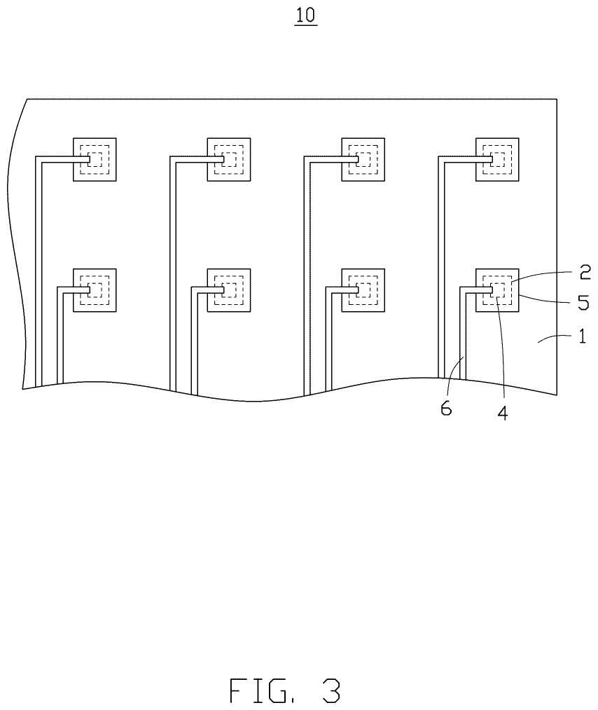

As shown in FIG. 3, in this embodiment, the LEDs 2 on the substrate 1 are spaced apart from each other, and the LEDs 2 are arranged in an array including a plurality of rows and a plurality of columns. The light-emitting diodes 2 emit source light, respectively. In this embodiment, the display device 100 defines a plurality of pixel areas arranged in an array including a plurality of rows and a plurality of columns. Each pixel area is provided with three adjacent light-emitting diodes 2, and the three adjacent light-emitting diodes 2 in the same pixel area are configured to emit red, green, and blue source light, respectively. Light from the pixel areas displays an image. In this embodiment, each light-emitting diode 2 can be a miniature inorganic LED, a micro inorganic LED, an organic LED, or the like.

As shown in FIG. 2, in this embodiment, each light-emitting diode 2 is a vertical light-emitting diode. That is, each light-emitting diode 2 includes a first electrode 21, a second electrode 22, and a light-emitting layer 23 between the first electrode 21 and the second electrode 22. That is, the first electrode 21, the light-emitting layer 23, and the second electrode 22 are stacked in turn. In this embodiment, the first electrode 21 is closer than the second electrode 22 to the substrate 1.

The first electrode 21 and the second electrode 22 include conductive materials for transmitting electrical signals. The light-emitting layer 23 includes light-emitting material. When the first electrode 21 and the second electrode 22 receive electrical signals and a preset voltage difference is formed between two sides of the light-emitting layer 23, the light-emitting material is stimulated to emit light, so that the light-emitting layer 23 emits light. That is, the light-emitting diode 2 emits source light. In this embodiment, each light-emitting diode 2 emits the source light in a direction mainly away from the substrate 1.

The light-emitting assembly 10 further includes an insulating layer 3. The insulating layer 3 is on the surface of the substrate 1 having the light-emitting diodes 2 and covers all the light-emitting diodes 2. That is, each light-emitting diode 2 is embedded in the insulating layer 3. In this embodiment, the insulating layer 3 is made of insulating and at least translucent material.

The light-emitting assembly 10 further includes a plurality of connection pads 4 electrically connected to the light-emitting diodes 2 in a one-to-one manner. In this embodiment, each connection pad 4 is on a side of the second electrode 22 away from the substrate 1 and is electrically connected to the second electrode 22. In this embodiment, each connection pad 4 is embedded in the insulating layer 3, and a surface of each connection pad 4 away from the substrate 1 is exposed from the insulating layer 3.

The light-emitting assembly 10 further includes a plurality of transparent electrodes 5 electrically connected to the light-emitting diodes 2 in a one-to-one manner. In this embodiment, each transparent electrode 5 is on the side of one second electrode 22 away from the substrate 1. In this embodiment, each transparent electrode 5 is on a side of one connection pad 4 away from the substrate 1 and at least partially covers the surface of the connection pad 4 exposed from the insulating layer 3. That is, in this embodiment, each connection pad 4 is electrically connected between one second electrode 22 and one transparent electrode 5, and each transparent electrode 5 is on a surface of the insulating layer 3 away from the substrate 1.

The light-emitting assembly 10 further includes a plurality of wires 6 connected to the light-emitting diodes 2 in a one-to-one manner. Each wire 6 is electrically connected to one light-emitting diode 2 through one transparent electrode 5. In this embodiment, each wire 6 is on the surface of the insulating layer 3 away from the substrate 1.

In this embodiment, the transparent electrodes 5 are made of transparent conductive material, and the connection pads 4 and the wires 6 are made of metal (such as copper).

In a manufacture process of the light-emitting assembly 10 of this embodiment, a substrate 1 is provided, and the light-emitting diodes 2, the connection pads 4, the transparent electrodes 5, and the wires 6 are sequentially formed on the substrate 1. The wires 6 need to be precisely connected with the transparent electrodes 5 to ensure that a complete current loop is formed in the light-emitting assembly 10.

In a comparative embodiment, the transparent electrodes 5 are not included in a light-emitting assembly, and each wire is directly in electrical contact with a connection pad on a light-emitting diode. It is difficult to precisely align the wire and the connection pad because of the small sizes of the light-emitting diode and the connection pad, which may cause alignment deviation and not form a current loop correctly.

In this embodiment, an orthographic projection area of each transparent electrode 5 on the substrate 1 is larger than an orthographic projection area of each of the connection pads 4 on the substrate 1. That is, in a direction parallel to the substrate 1, an area of each transparent electrode 5 is larger than an area of each connection pad 4. Since each transparent electrode 5 has a larger area than each connection pad 4, alignment of the wires 6 with each transparent electrode 5 is easier than aligning the wires 6 with each connection pad 4. The wires 6 and the transparent electrodes 5 can be in electrical contact even if the wires 6 deviate from the center of the transparent electrodes 5.

In this embodiment, the orthographic projection of each transparent electrode 5 on the substrate 1 completely covers the orthographic projection of the connection pad 4 on the substrate 1, so that a facing area of the transparent electrode 5 and the connection pad 4 is maximized, and a contact area of the transparent electrode 5 and the connection pad 4 is maximized, which is conducive to improving a reliability of electrical connection.

In another embodiment of this embodiment, the connection pads 4 are not included, and the transparent electrodes 5 are in direct electrical contact with the second electrodes 22. In another embodiment, the orthographic projection area of each transparent electrode 5 on the substrate 1 is larger than the orthographic projection area of each second electrode 22 on the substrate 1. That is, in a direction parallel to the substrate 1, an area of each transparent electrode 5 is larger than an area of each second electrode 22 to which it is electrically connected. Since each transparent electrode 5 has a larger area than each second electrode 2, it is easier to align the wires 6 with each transparent electrode 5 than aligning the wires 6 with each second electrode 2. The wires 6 and the transparent electrodes 5 can be in electrical contact even if the wires 6 deviate from the center of the transparent electrodes 5.

Furthermore, in this further embodiment, the orthographic projection of each transparent electrode 5 on the substrate 1 completely covers the orthographic projection of each second electrode 22 on the substrate 1, so that a facing area between the transparent electrode 5 and the second electrode 22 is maximized. Therefore, a contact area between the transparent electrode 5 and the second electrode 22 is maximized, which is beneficial to improve reliability of electrical connection.

In this embodiment, the driving circuit 12 is used to output the first driving signal, and each wire 6 is used to receive and transmit a second driving signal. The first electrode 21 is used to receive the first driving signal, and the second electrode 22 is used to receive the second driving signal. The first driving signal and the second driving signal cause a voltage difference between two sides of the light-emitting layer 23 so that the light-emitting diode 2 can emit light. When the voltage difference formed between the two sides of the light-emitting layer 23 changes, a light intensity of the source light changes with the voltage difference. By controlling values of the first driving signal and the second driving signal, the intensity of the source light emitted by each light-emitting diode 2 can be adjusted, so that the light-emitting diodes 2 cooperate to display an image.

In this embodiment, each wire 6 extends on the surface of the insulating layer 3 away from the substrate 1 and is finally connected to a circuit board or a driving chip (not shown).

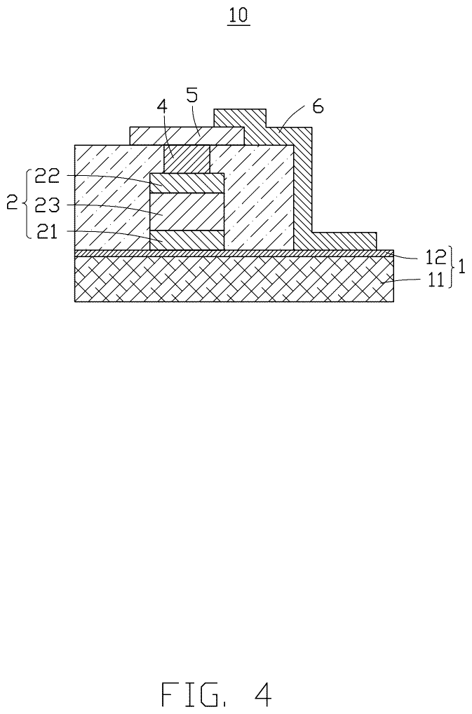

In the modified embodiment of this embodiment, as shown in FIG. 4, a part of each wire 6 extends on the surface of the insulating layer 3 away from the substrate 1, and the other part of each wire 6 extends to the surface of the substrate 1 having the light-emitting diodes 2 and is electrically connected to the driving circuit 12. That is, in this further embodiment, the driving circuit 12 is further electrically connected to the wires 6 to output the second driving signal to each wire 6.

In another embodiment, the light-emitting assembly 10 may further include bonding material (such as solder paste, not shown) between each light-emitting diode 2 and the substrate 1. The bonding material is used to fix the light-emitting diodes 2 on the substrate 1.

In another embodiment, the light-emitting assembly 10 may be used as a lighting device or a stage lighting device in addition to use as a display device, wherein the light-emitting diodes 2 are used to emit source light of the same color (such as white).

The light-emitting assembly 10 of this embodiment includes the light-emitting diodes 2 and the transparent electrodes 5 electrically connected to the light-emitting diodes 2. Each light-emitting diode 2 includes a second electrode 22. The orthographic projection area of each transparent electrode 5 on the substrate 1 is larger than that of each second electrode 22 on the substrate, which increases the size and therefore tolerance of alignment area between the transparent electrodes 5 and the wires 6, thereby improving a manufacturing yield of the light-emitting assembly 10.

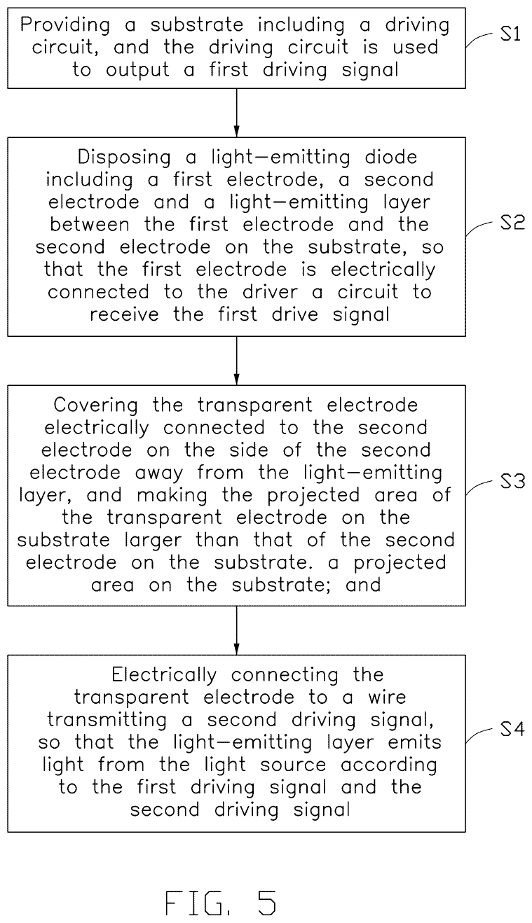

As shown in FIG. 5, a flowchart is presented in accordance with an example embodiment which is being thus illustrated. The example method for making light-emitting assembly is provided by way of example, as there are a variety of ways to carry out the method. The method for making light-emitting assembly described below can be carried out using the configurations illustrated in FIGS. 2, 3, and 4, for example, and various elements of these figures are referenced in explaining example method for making light-emitting assembly. Each block shown in FIG. 5 represents one or more processes, methods, or subroutines, carried out in the method for making light-emitting assembly. Additionally, the illustrated order of blocks is by example only and the order of the blocks can change according to the present disclosure. The exemplary method for making light-emitting assembly can begin at block S1. The method for making light-emitting assembly includes:
block S1, providing a substrate including a driving circuit, and the driving circuit being used to output a first driving signal;
block S2, forming a light-emitting diode including a first electrode, a second electrode, and a light-emitting layer between the first electrode and the second electrode on the substrate, the first electrode being electrically connected to the driving circuit to receive the first drive signal;
block S3, forming a transparent electrode on a side of the second electrode away from the light-emitting layer, the transparent electrode covering and connected to the second electrode, and an orthographic projection area of the transparent electrode on the substrate being larger than that of the second electrode on the substrate; and
block S4, connecting the transparent electrode to a wire transmitting a second driving signal, so that the light-emitting layer emits source light according to the first driving signal and the second driving signal.

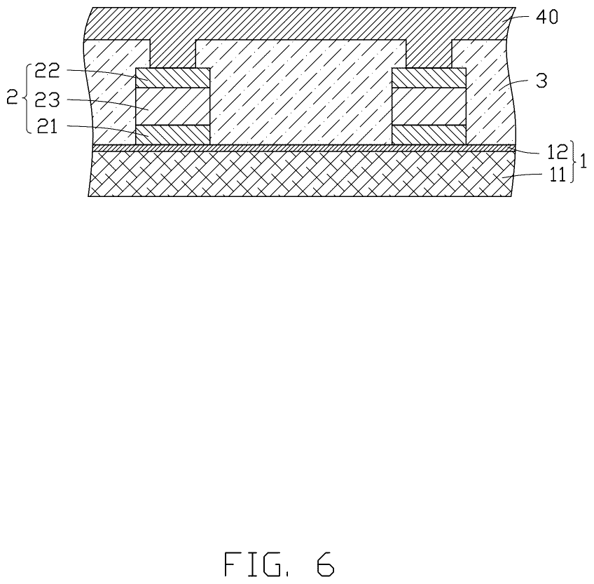

As shown in FIG. 6, in block S2, a plurality of light-emitting diodes 2 are fixed to the surface of the substrate 1 having the driving circuit 12, and the insulating layer 3 covering the light-emitting diodes 2 is formed. Each light-emitting diode 2 includes a first electrode 21, a second electrode 22, and a light-emitting layer 23 between the first electrode 21 and the second electrode 22, wherein the first electrode 21 is closer than the second electrode 22 to the substrate 1, so that the first electrode 21 electrically connected to the driving circuit 12. The insulating layer 3 completely covers the light-emitting diodes 2.

In block S2, the insulating layer 3 is etched, such as by laser etching, corrosive liquid or etching gas etching, so that the second electrode 22 of each light-emitting diode 2 is exposed from the insulating layer 3.

In block S2, a metal layer 40 is formed on the side of the insulating layer 3 away from the substrate 1 by evaporation, printing, inkjet printing, or a physical vapor deposition (PVD) process.

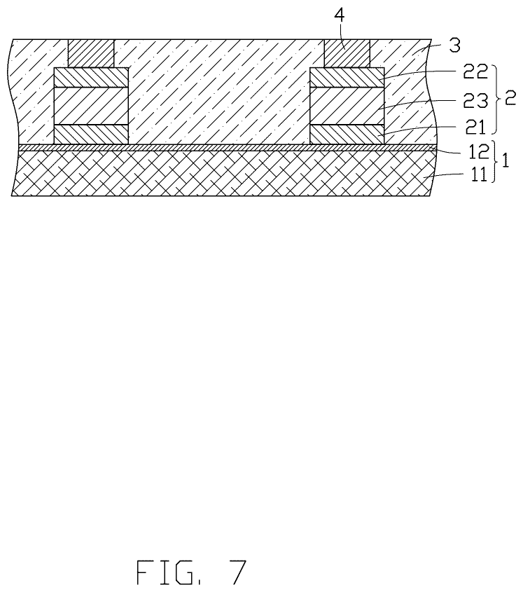

As shown in FIG. 7, in block S2, the metal layer 40 is patterned by chemical mechanical polishing, metal stripping process, yellow light, etc. to form the connection pads 4, and each connection pad 4 is connected to one first light-emitting diode 2. The second electrodes 22 are embedded in the insulating layer 3. In this embodiment, the surface of each connection pad 4 away from the substrate 1 is exposed from the insulation layer 3 and is flush with the surface of the insulating layer 3 away from the substrate 1.

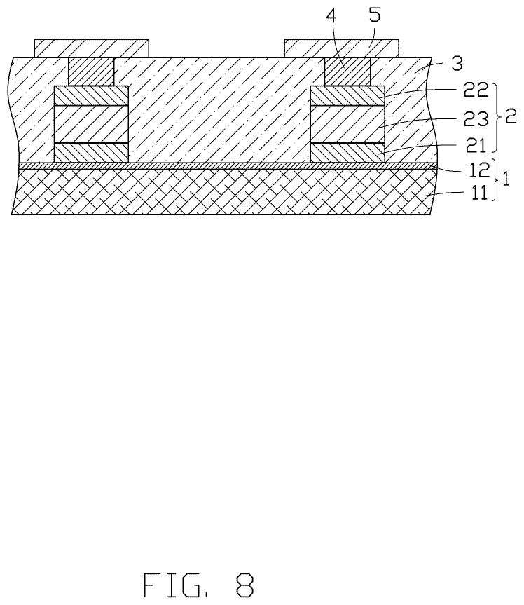

As shown in FIG. 8, in block S3, transparent electrodes 5 are formed on the surface of the insulating layer 3 away from the substrate 1. Each transparent electrode 5 is electrically connected to one connection pad 4. In this embodiment, an orthographic projection area of each transparent electrode 5 on the substrate 1 is larger than an orthographic projection area of each second electrode 22 on the substrate 1, and also larger than an orthographic projection area of each connection pad 4 on the substrate 1. In this embodiment, the orthographic projection of each transparent electrode 5 on the substrate 1 completely covers the orthographic projection of each second electrode 22 on the substrate 1, and also completely covers the orthographic projection of each connection pad 4 on the substrate 1.

In block S4, wires 6 are formed on the surface of the insulating layer 3 away from the substrate 1, so that each wire 6 is electrically connected to one transparent electrode 5, to obtain the light-emitting assembly 10 shown in FIG. 2.

The method for making light-emitting assembly in this embodiment is beneficial for reducing the alignment difficulty of conductive structures (transparent electrodes and the second electrode) in the light-emitting assembly 10, thereby improving the manufacturing yield of the light-emitting assembly 10.

### Second Embodiment

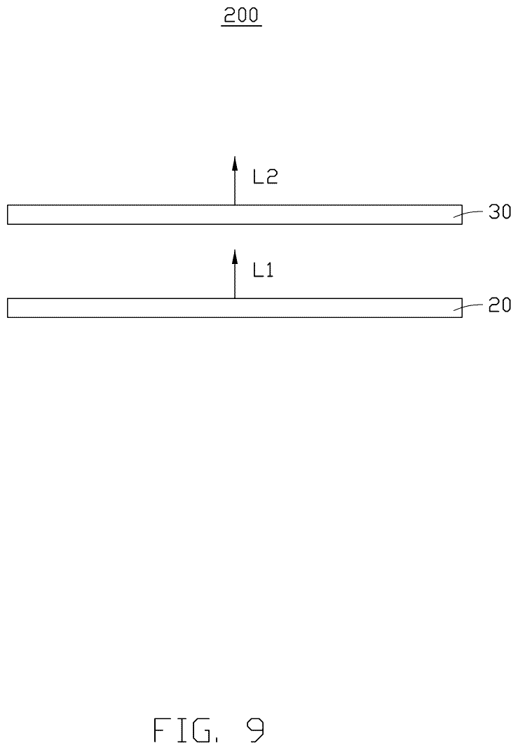

The display device 200 of this embodiment is shown in FIG. 9. A main difference between the display device 200 and the display device 100 of the first embodiment is that the display device 200 is not a self-illuminating display device.

As shown in FIG. 8, the display device 200 of this embodiment includes a light-emitting assembly 20 and a display assembly 30 stacked together. The light-emitting assembly 20 is used to provide the source light L1, the display assembly 30 is on the optical path of the source light L1 and is configured to modulate the source light L1 so that image light L2 displays an image. In this embodiment, the display assembly 30 is, for example, a liquid crystal display assembly, which includes structures such as a liquid crystal layer, a polarizer, and an array substrate.

In this embodiment, each light-emitting diode 2 of the light-emitting assembly 20 is used to emit light of the same color.

Other structures and manufacturing methods in the light-emitting assembly 20 in this embodiment are as described in the first embodiment.

The display device 200 and the light-emitting assembly 20 of this embodiment also take the beneficial effects described in the first embodiment.

The embodiments shown and described above are only examples. Many details are often found in the art such as the other features of a light-emitting assembly and a display device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A method of making light-emitting assembly, the method comprising:
providing a substrate comprising a driving circuit configured for outputting a first driving signal;
forming a plurality of light-emitting diodes on the substrate, each of the plurality of light-emitting diode comprising a first electrode, a second electrode, and a light-emitting layer between the first electrode and the second electrode, wherein the first electrode is connected to the driving circuit to receive the first driving signal;
forming a plurality of transparent electrodes electrically insulated from each other, wherein each of the plurality of light-emitting diodes is connected to a corresponding one of the plurality of transparent electrodes, and the plurality of transparent electrodes is on a side of the second electrode away from the light-emitting layer and is connected to the second electrode, and an orthographic projection area of each of the plurality of transparent electrodes on the substrate is larger than an orthographic projection area of the second electrode on the substrate; and
connecting each of the plurality of transparent electrodes to a wire wherein in response to the wire transmitting a second driving signal, the light-emitting layer emits source light according to the first driving signal and the second driving signal.

2. The method of making light-emitting assembly of claim 1, wherein the orthographic projection of each of the plurality of transparent electrodes on the substrate completely covers the orthographic projection of the second electrode on the substrate.

3. The method of making light-emitting assembly of claim 1, further comprising: providing a plurality of connection pads and connecting each of the plurality of connection pads between the second electrode and corresponding one of the plurality of transparent electrodes;
wherein the orthographic projection area of each of the plurality of transparent electrodes on the substrate is larger than an orthographic projection area of each of the plurality of connection pads on the substrate.

4. The method of making light-emitting assembly of claim 3, wherein each of the plurality of connection pads is made of metal.

5. The method of making light-emitting assembly of claim 3, wherein the orthographic projection of each of the plurality of transparent electrodes on the substrate completely covers the orthographic projection of corresponding one of the plurality of connection pads on the substrate.

6. The method of making light-emitting assembly of claim 1, further comprising electrically connecting the wire to the driving circuit, and configuring the driving circuit to output the second driving signal.

7. The method of making light-emitting assembly of claim 1, further comprising: covering an insulation layer on a surface of the substrate having the plurality of light-emitting diodes,
wherein each of the plurality of light-emitting diodes is embedded in the insulation layer, the plurality of transparent electrodes are on a side of the insulation layer away from the substrate; and
arranging the wire at least partially on the side of the insulation layer away from the substrate.

8. The method of making light-emitting assembly of claim 7, further comprising: etching the insulating layer to expose the second electrode of each of the plurality of light-emitting diodes from the insulating layer.

9. The method of making light-emitting assembly of claim 7, wherein the wire is further arranged to extend on a surface of the insulation layer away from the substrate.

10. The method of making light-emitting assembly of claim 7, wherein the wire is further arranged to extend a part of the wire on to a surface of the insulation layer away from the substrate, extend other part of the wire on to a surface of the substrate having the plurality of light emitting diodes, and electrically connecting the wire to the driving circuit.

11. The method of making light-emitting assembly of claim 1, wherein the plurality of light-emitting diodes are formed to emit the source light of a same color.

12. The method of making light-emitting assembly of claim 11, further comprising configuring the source light for illumination or displaying images.

13. The method of making light-emitting assembly of claim 1, wherein the plurality of light-emitting diodes are formed to emit the source light of different color, and the method further comprising configuring the source light to display an image.

14. The method of making light-emitting assembly of claim 13, wherein the source light comprises red, green, and blue light.

15. The method of making light-emitting assembly of claim 1, wherein the wire is made of metal.
